(19) United States
(12) Patent Application Publication
(10) Pub. No.: US 2004/0197992 A1
(43) Pub. Date: Oct. 7, 2004

(54) Floating gates having improved coupling ratios and fabrication method thereof

(76) Inventor: Hsiao-Ying Yang, Hsinchu (TW)

Correspondence Address: BIRCH STEWART KOLASCH & BIRCH, PO BOX 747, FALLS CHURCH, VA, 22040-0747, US

(21) Appl. No.: 10/405,613

(22) Filed: Apr. 3, 2003

(51) Int. Cl. H01L 21/336

(52) U.S. Cl. 438/257; 438/264; 438/265

(57) ABSTRACT

A method for fabricating floating gates having improved coupling ratios. The method includes forming a tunneling dielectric layer, a conductive layer and an insulation layer sequentially on a semiconductor substrate, defining and etching the tunneling dielectric layer, the conductive layer, the insulation layer and the semiconductor substrate to form two trenches, filling the two trenches with insulation material to a level lower than the conductive layer, thereby forming shallow trench isolation structures, removing the insulation layer, and forming a pair of conductive spacers on the two sidewalls of the conductive layer, such that the tops of the conductive spacers are lower than the surface of the conductive layer, with the conductive spacers and the conductive layer form the floating gate.

### BACKGROUND OF THE INVENTION

1. Field of the Invention

The present invention relates to a method for fabricating non-volatile memory, and in particular to a method that enables the fabrication of floating gates having improved coupling ratios.

2. Description of the Related Art

High density non-volatile memory is a critical product as it is widely applied in the semiconductor industry. Key points are low production costs and small sizes of a single memory cell. However, it is very difficult to reduce the sizes of memory cells when conventional LOCOS (local oxidation of silicon) is adopted to fabricate non-volatile memory. The primary reason is that the isolation oxide formed is quite large, thereby restricting the downsizing of memory cell.

In order to reduce sizes of memory cells, another isolation method, i.e. shallow trench isolation (STI) has been applied in the fabrication of non-volatile memory in place of the conventional LOCOS. STI utilizes a shallow trench structure to isolate active regions, which effectively improves the integration of elements. Nevertheless, the continuing reduction in element sizes also leads to the reduction of surface areas of floating gates. Consequently, effective capacitance between the floating gates and control gates is reduced, thus lowering the final capacitive coupling ratio. The capacitive coupling ratio is describes the parameter for the voltage applied onto the control gate when coupled to the floating gate. Memory having insufficient capacitive coupling ratio results in poor programming and access speed.

The capacitive coupling ratio (Cp) is defined as follows:

$$Cp = \frac{Ccf}{Ccf + Cfs}$$

where Ccf represents the capacitance between the control gate and the floating gate, and Cfs represents the capacitance between the floating gate and the substrate.

In order to increase the programming and access speed of non-volatile memory, there have been many proposals to increase the coupling ratio. It is observed from the above formula that when Ccf increases, Cp also increases. Therefore, by increasing the capacitance area between the floating gate and the control gate, Ccf is increased thereby improving the coupling ratio Cp.

U.S. Pat. No. 6,171,909 and U.S. Pat. No. 6,261,903 disclose methods for forming stacked gates of flash memory. Coupling ratio of the stacked gates is increased by the formation of conductive spacers. The conductive spacers are parts of floating gates, used to increase the capacitive area between the floating gate and the control gate.

The floating gate of the '903 patent is shown in FIGS. 1A and 1B, where 10 represents the substrate, 12 is the tunneling dielectric layer, 14 is the conductive spacer, 18 is the insulation layer, such as SiN, and 16 is a conductive layer of polysilicon. The conductive spacer 14 is next to conductive layer 16 and insulation layer 18, as shown in FIG. 1A. After removal of the insulation layer 18, a protruding structure as shown in FIG. 1B is formed. Although capacitive area between the floating gate and the control gate is increased, the protruding structure easily causes discharge at the pointed end. At later stages, the protruding structure easily breaks and causes particle problems. Therefore, this method exhibits a potential problem of semiconductor pollution.

In addition, U.S. Pat. No. 6,331,464 provides a process for improving coupling ratio of flash memory by increasing the capacitive coupling area. The method features the steps of forming the protruding conductive spacers followed by grinding the pointed end to avoid discharge. However, the method still cannot completely solve particle pollution problems.

### SUMMARY OF THE INVENTION

Accordingly, an object of the invention is to provide a floating gate structure having improved coupling ratio and a method fabricating the same that is able to avoid conventional problem associated with particles caused by the protruding structure of floating gates.

The method for fabricating floating gates having improved coupling ratio provided in the invention features an improved process that forms non-protruding conductive spacers for the floating gate. The method includes forming a tunneling dielectric layer, a conductive layer and an insulation layer sequentially on a semiconductor substrate, defining and etching the tunneling dielectric layer, the conductive layer, the insulation layer and the semiconductor substrate to form two trenches, filling the two trenches with insulation material to a level lower than the conductive layer, thereby forming shallow trench isolation structures, removing the insulation layer, and forming a pair of conductive spacers on the two sidewalls of the conductive layer, wherein the tops of the conductive spacers are lower than the surface of the conductive layer, with the conductive spacers and the conductive layer forming the floating gate.

According to another aspect of the invention, a method for fabricating a flash memory having improved coupling ratio comprises forming a tunneling dielectric layer, a conductive layer and an insulation layer sequentially on a semiconductor substrate, defining and etching the tunneling dielectric layer, the conductive layer, the insulation layer and the semiconductor substrate to form two trenches, filling the two trenches with insulation material to a level lower than the conductive layer, thereby forming shallow trench isolation structures, removing the insulation layer, forming a pair of conductive spacers on the two sidewalls of the conductive layer, wherein the conductive spacers and the conductive layer form a floating gate, and forming a gate inter dielectric layer and a controlling gate sequentially on the shallow trench isolation structures and the floating gate to form a flash memory.

According to the method described, the floating structure provided in the invention comprises a semiconductor substrate, a tunneling dielectric layer formed on the semiconductor substrate, a conductive layer, formed on the tunneling dielectric layer, and a conductive spacer formed on the sidewalls of the conductive layer, wherein the tops of the conductive spacers are lower than the surface of the conductive layer, with the conductive spacers and the conductive layer forming the floating gate.

According to the invention, not only is the capacitor contact region of the floating gate improved, increasing the coupling ratio, the conventional problem of particle pollution caused by broken protruding structure is also avoided. Consequently, production yield is increased thereby ensuring the performance stability of the elements.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1B are cross sections of a conventional floating gate;

FIGS. 2A˜2F illustrate cross sections of the process according to the method for fabricating floating gates having improved coupling ratio of the invention.

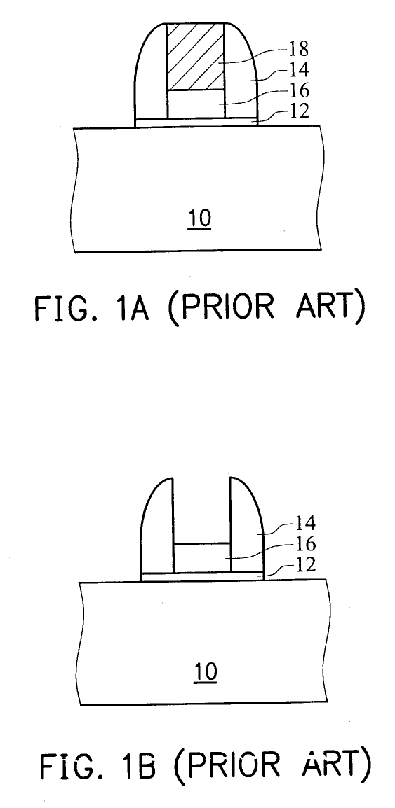

### DETAILED DESCRIPTION OF THE INVENTION

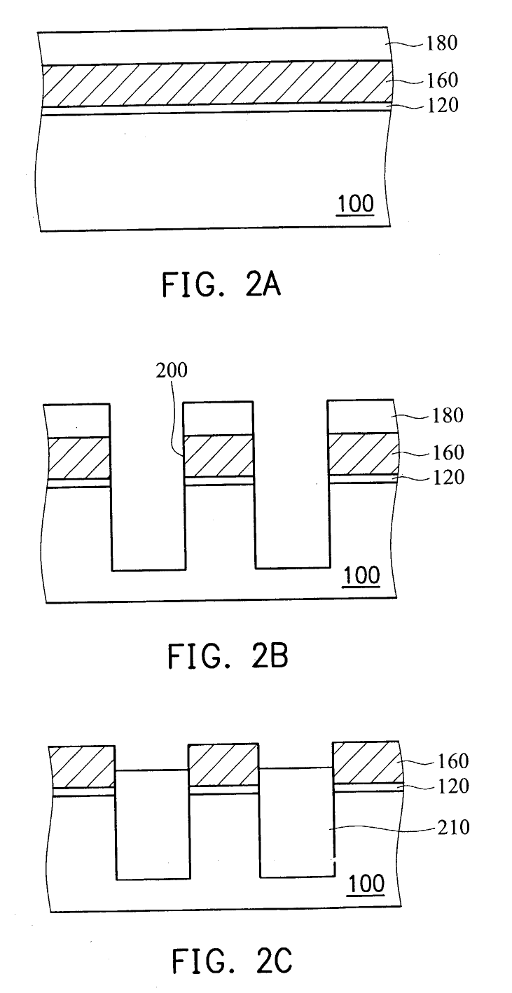

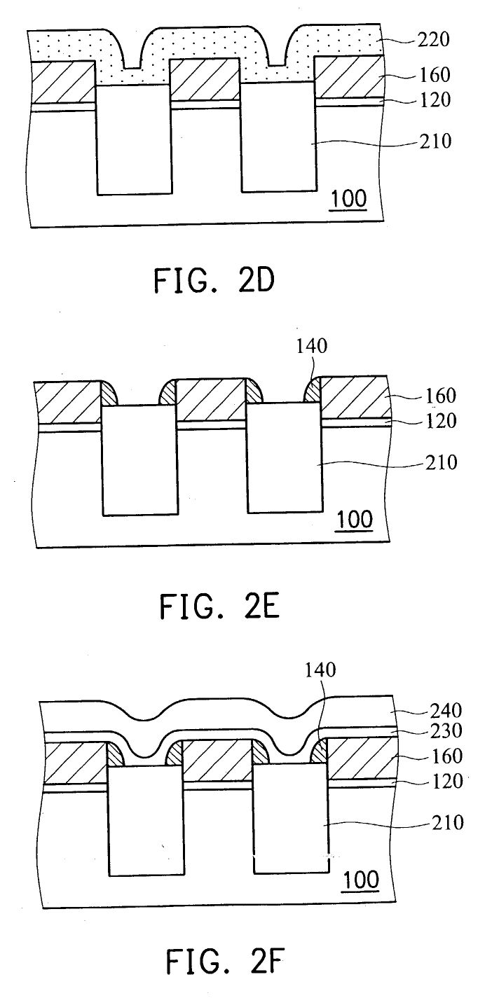

FIGS. 2A˜2F which illustrate cross sections of the process according to the method for fabricating floating gates having improved coupling ratios of the invention.

Firstly, in FIG. 2A, a tunneling dielectric layer 120, a conductive layer 160 and an insulation layer 180 are sequentially formed on a semiconductor substrate 100. The tunneling dielectric layer is oxide or oxynitride, such as N₂O, preferably formed by thermal oxidation at a temperature range of 750˜950° C., conventional atmospheric pressure CVD (APCVD), or low pressure CVD (LPCVD). Preferable thickness of the tunneling dielectric layer is 60˜120 angstroms. Conductive layer is doped polysilicon, doped amorphous silicon, undoped polysilicon, undoped amorphous silicon or polycide, such as WSi, with doped polysilicon preferred. Preferable thickness is 500˜3000 angstroms. Insulation layer is preferably formed by deposition using dielectric material, such as SiN to a preferable thickness of 1200˜2500 angstroms.

Next, a photoresist mask (not shown) covers the area that forms the active element at later stage, followed by dry etching of the tunneling dielectric layer 120, conductive layer 160 and insulation layer 180. The substrate 100 is etched to a predetermined depth to form a number of shallow trenches 200, as shown in FIG. 2.

The photoresist pattern is removed after the completion of etching, followed by high density plasma deposition (HDPCVD) or low pressure CVD (LPCVD) to fill insulation material, such as oxide in the trench 200. Excess oxide in the trench can be removed by etch back or chemical mechanical polishing (CMP) to lower the surface of the oxide below the surface of the conductive layer. Insulation layer 180 is removed simultaneously. By doing so, dent shallow trench isolation regions 210 isolating a number of conductive layer 160 are formed, as shown in FIG. 2C.

The critical steps are as follows, refer to FIG. 2D. A conductive material 220 is formed entirely on the surface of the conductive layer 160 and the shallow trench isolation 210. The conductive material is preferably doped polysilicon, doped amorphous silicon, undoped polysilicon, undoped amorphous silicon or polycide, such as WSi, wherein polysilicon is preferred. Then, anistropic etching is performed to form two conductive spacers 140 on the sidewalls of the conductive layer 160, as shown in FIG. 2E, to expose oxide of the shallow trench isolation 210. The conductive layer 160 and the conductive spacers 140 thus form a floating gate. It should be noted that the tops of the conductive spacers 140 level with the surface of the conductive layer 160.

Next, as shown in FIG. 2F, a gate inter dielectric layer 230 and a second conductive layer 240 as a control gate are sequentially formed on the floating gate (160 and 140) by conventional methods. The gate inter dielectric layer 230 is usually oxide/nitride/oxide (ONO), nitride/oxide (N/O), MM′M″ TiO3 formed by Ta2O5 (BST), wherein M comprises at least Ba, Sr, Pb, etc. Examples are BaₓSr₁₋ₓTiO₃, BaTiO₃, SrTiO₃. The second conductive material is preferably doped polysilicon, doped amorphous silicon, undoped polysilicon, undoped amorphous silicon or polycide, such as WSi, or self-aligned polycide (Salicide). Finally, a mask and an etching step are carried out to define the second conductive layer as a control gate thereby forming a floating gate having an improved coupling ratio for non-volatile memory.

It is observed from FIG. 2F that the non-volatile memory of the invention comprises at least two isolation structures 210 having surfaces lower than the substrate 100. Two conductive spacers 140 are formed on the two sidewalls of the isolation structures 210, which form a floating gate with the conductive layer 160. According to the invention, the tops of the conductive spacers 140 level with the surface of the conductive layer 160, unlike the overhang structure formed by conventional methods. Hence, problems associated with the protruding structure of the conductive spacers are avoided in the invention by having a smooth surface formed by the conductive spacers 140 and the conductive layer 160.

According to the invention, the advantages include increased capacitive area between the floating gate and the control gate, thereby increasing the coupling ratio, and prevention from particle problems caused by break of conventional protruding structures at later stages of the process. Consequently, production yield is increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for fabricating floating gates, comprising:
forming a tunneling dielectric layer, a polycide layer and an insulation layer sequentially on a semiconductor substrate;
defining and etching the tunneling dielectric layer, the polycide layer, the insulation layer and the semiconductor substrate to form two trenches;
filling the two trenches with insulation material to a level between the top and bottom of the polycide layer, thereby forming shallow trench isolation structures;
removing the insulation layer; and
forming a pair of polycide spacers on the two sidewalls of the polycide layer, wherein the tops of the polycide spacers level with the surface of the polycide layer and the bottoms of the policide spacers are on the level above the tunneling dielectric layer, with the polycide spacers and the polycide layer forming the floating gate.

2-3. (canceled)

4. The method as claimed in claim 1, wherein the tunneling dielectric layer is oxide or oxynitride.

5. The method as claimed in claim 1, wherein the insulation layer is nitride.

6. A floating gate having improved coupling ratio, comprising:
a semiconductor substrate;
a tunneling dielectric layer formed on the semiconductor substrate;
a conductive layer, formed on the tunneling dielectric layer; and
a plurality of conductive spacers, formed on the sidewalls of the conductive layer, and the tops of the conductive spacers level with the surface of the conductive layer, with the conductive spacers and the conductive layer forming the floating gate.

7. The floating gate as claimed in claim 6, further comprising two neighboring shallow trench isolation structures, and the tunneling dielectric layer located between the two shallow trench isolation structures.

8. The floating gate as claimed in claim 6, wherein the conductive layer is doped polysilicon, doped amorphous silicon, undoped polysilicon, undoped amorphous silicon or polycide.

9. The floating gate as claimed in claim 6, wherein the conductive spacers are doped polysilicon, doped amorphous silicon, undoped polysilicon, undoped amorphous silicon or polycide.

10. The floating gate as claimed in claim 6, wherein the tunneling dielectric layer is oxide or oxynitride.

11. The floating gate as claimed in claim 6, wherein the insulation layer is nitride.

12. A method for a flash memory having improved coupling ratio, comprising:
forming a tunneling dielectric layer, a polycide layer and an insulation layer sequentially on a semiconductor substrate;
defining and etching the tunneling dielectric layer, the polycide layer, the insulation layer and the semiconductor substrate to form two trenches;
filling the two trenches with insulation material to a level between the top and bottom of the polycide layer, thereby forming shallow trench isolation structures;
removing the insulation layer;
forming a pair of polycide spacers on the two sidewalls of the polycide layer, wherein the tops of the polycide spacers level with the surface of the polycide layer and the bottoms of the policide spacers are on the level above the tunneling dielectric layer, the polycide spacers and the polycide layer forming a floating gate; and
forming a gate inter dielectric layer and a controlling gate sequentially on the shallow trench isolation structures and the floating gate to form a flash memory.

13. The method as claimed in claim 12, wherein the gate inter dielectric layer is silicon oxide/silicon nitride/silicon oxide (ONO) or Ta₂O₅.

14. The method as claimed in claim 12, wherein the gate inter dielectric layer is material having high dielectric constant.

15. The method as claimed in claim 14, wherein the material having high dielectric constant is BaₓSr₁₋ₓTiO₃, BaTiO₃, SrTiO₃ or (M)TiO₃, wherein M is at least Ba, Sr or Pb.

16. (canceled)

17. The method as claimed in claim 12, wherein the tunneling dielectric layer is oxide or oxynitride.

18. The method as claimed in claim 12, wherein the insulation layer is nitride.
